(19) United States
(12) Patent Application Publication
(10) Pub. No.: US 2021/0006042 A1
(43) Pub. Date: Jan. 7, 2021

(54) GROUP-III NITRIDE SEMICONDUCTOR LASER DEVICE

(71) Applicant: Panasonic Intellectual Property Management Co., Ltd., Osaka (JP)

(72) Inventors: AKIHIKO ISHIBASHI, Osaka (JP); HIROSHI OHNO, Osaka (JP); JUNICHI TAKINO, Osaka (JP); TOMOAKI SUMI, Osaka (JP)

(21) Appl. No.: 16/912,018

(22) Filed: Jun. 25, 2020

(30) Foreign Application Priority Data
Jul. 3, 2019 (JP) 2019-124662

(51) Int. Cl. H01S 5/343; H01S 5/22; H01S 5/20; H01S 5/042

(52) U.S. Cl. CPC H01S 5/34333; H01S 5/22; H01S 5/2081; H01S 2301/18; H01S 5/2205; H01S 2304/04; H01S 5/04256

(57) ABSTRACT

A group-III nitride semiconductor laser device includes a GaN substrate, and an active layer provided on the GaN substrate, in which the GaN substrate has an oxygen concentration of 5×10¹⁹ cm⁻³ or more, and an absorption coefficient of the GaN substrate with respect to an oscillation wavelength of the active layer is greater than an absorption coefficient of the active layer with respect to the oscillation wavelength.

### BACKGROUND

### 1. Technical Field

The present disclosure relates to a group-III nitride semiconductor laser device.

### 2. Description of the Related Art

Group-III nitride crystals such as GaN are expected to be applied to next-generation optical devices such as a high-power light emitting diode (LED) for illumination, a laser display, and a laser diode (LD) for a laser processing machine, new-generation electronic devices such as a high-power transistor mounted on an electric vehicle (EV) and a plug-in hybrid vehicle (PHV), or the like. In order to improve performance of the optical and electronic devices using the group-III nitride crystals, it is desirable that a substrate as a base material is constituted with a high-quality group-III nitride single crystal substrate such as GaN.

In order to produce the high-quality group-III nitride single crystal substrate, research and development have been made on a hydride vapor phase epitaxy (HVPE) method, a Na flux method, an ammonothermal method, and the like. Further, an oxide vapor phase epitaxy (OVPE) method using a group-III oxide as a raw material has been devised (for example, see International Publication No. WO 2015/053341). The reaction system in this OVPE method is as follows.

(1) First, liquid Ga is heated, and in this state, H₂O gas, which is a reactive gas, is introduced into the liquid GA. The introduced H₂O gas reacts with Ga to generate Ga₂O gas (Formula (I) below).

(2) Then, NH₃ gas is introduced and reacted with the generated Ga₂O gas to generate a GaN crystal on a seed substrate (Formula (II) below).

2Ga+H₂O→Ga₂O+H₂ (I)

Ga₂O+2NH₃→2GaN+H₂O+2H₂ (II)

In order to improve the performance of a laser diode or a power device, it is desired to reduce a resistance of the group-III nitride substrate as a base material. Oxygen doping in group-III nitride crystal has been devised as means for reducing the resistance (for example, see Japanese Patent Unexamined Publication No. 2006-240988). It is also known that by performing high-concentration oxygen doping, a composite level is formed in a band gap of GaN, and the group-III nitride crystal absorbs blue to red visible light and is blackened.

As illustrated in FIG. 6, in a group-III nitride blue laser diode using GaN substrate 601, light 614 (hereinafter, referred to as stray light) leaked out from a waveguide centered on an active layer to the GaN substrate is guided into substrate 601. As a result, disturbance of a far-field pattern (FFP) of laser light, such as ripple 701, may occur as illustrated in FIG. 7. Thus, a configuration is disclosed in which light is confined to a multilayer structure forming a laser diode by making a value of an effective refractive index of the multilayer structure equal to or more than a value of the GaN substrate, such that stray light does not leak out to the GaN substrate (for example, see Japanese Patent Unexamined Publication No. 2001-85796).

### SUMMARY

According to the present disclosure, there is provided a group-III nitride semiconductor laser device including: a GaN substrate; and an active layer provided on the GaN substrate, in which the GaN substrate has an oxygen concentration of 5×10¹⁹ cm⁻³ or more, and an absorption coefficient of the GaN substrate with respect to an oscillation wavelength of the active layer is greater than an absorption coefficient of the active layer with respect to the oscillation wavelength.

### BRIEF DESCRIPTION OF THE DRAWINGS

FIG. 1 is a diagram illustrating a group-III nitride semiconductor laser device and a near-field pattern of a laser beam according to an exemplary embodiment of the present disclosure;

FIG. 2 is a diagram schematically illustrating a cross section of an apparatus for manufacturing a group-III nitride substrate according to the exemplary embodiment of the present disclosure;

FIG. 3 is a diagram showing a relationship between a concentration of an oxygen atom in the group-III nitride substrate and a full width at half maximum of an X-ray rocking curve according to the exemplary embodiment of the present disclosure;

FIG. 4A is a diagram showing a relationship between a concentration of oxygen atom in the group-III nitride substrate and an absorption coefficient of blue light according to the exemplary embodiment of the present disclosure, and FIG. 4B is a diagram showing a relationship between an absorption coefficient of the group-III nitride substrate and a wavelength of the group-III nitride substrate;

FIG. 5 is a diagram illustrating a far-field pattern of a laser beam of a group-III nitride semiconductor according to the exemplary embodiment of the present disclosure;

FIG. 6 is a diagram illustrating a group-III nitride semiconductor laser device and a near-field pattern of a laser beam according to a comparative example; and

FIG. 7 is a diagram illustrating a far-field pattern of laser beam of a group-III nitride semiconductor according to the comparative example.

### DETAILED DESCRIPTIONS

In order to make a value of an effective refractive index of a multilayer structure forming the laser diode equal to or more than a value of a GaN substrate, for example, it is required to adjust an In or Al composition (atomic concentration) of an InGaN active layer or AlGaN clad layer or a thickness of each of the InGaN active layer and the AlGaN clad layer, and distortion of the entire device increases in order to form a layer having a different lattice constant from the GaN substrate, which may cause a decrease in yield due to warpage or deterioration during energization.

The present disclosure is to provide a group-III nitride semiconductor laser device capable of obtaining a unimodal far-field pattern FFP.

According to a first aspect, a group-III nitride semiconductor laser device includes: a GaN substrate; and an active layer provided on the GaN substrate, in which the GaN substrate has an oxygen concentration of 5×10¹⁹ cm⁻³ or more, and an absorption coefficient of the GaN substrate with respect to an oscillation wavelength of the active layer is greater than an absorption coefficient of the active layer with respect to the oscillation wavelength.

According to a second aspect, in the group-III nitride semiconductor laser device according to the first aspect, the GaN substrate may have an oxygen concentration of 1×10²⁰ cm⁻³ or more.

According to a third aspect, in the group-III nitride semiconductor laser device according to the first or second aspect, the GaN substrate may have a light absorption coefficient of 10 cm⁻¹ or more.

According to a fourth aspect, in the group-III nitride semiconductor laser device according to any one of the first to third aspects, the GaN substrate may have an n-type electrical conductivity.

Hereinafter, a group-III nitride semiconductor laser device and a method of manufacturing the same according to an exemplary embodiment will be described with reference to the accompanying drawings. In the drawings, the same reference numerals are used to denote substantially the same members.

### First Exemplary Embodiment

### Group-III Nitride Semiconductor Laser Device

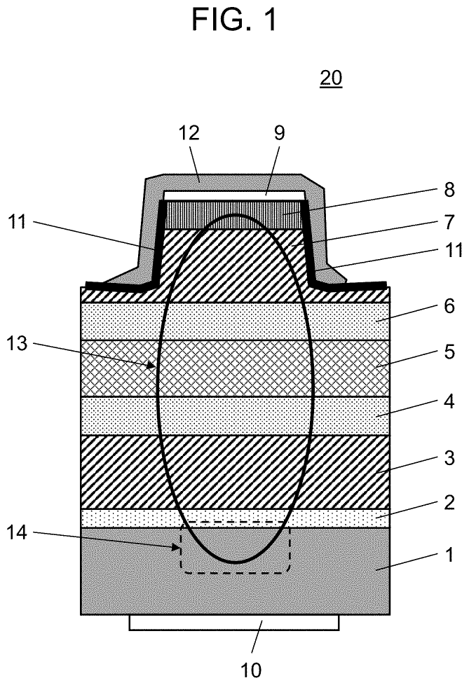

FIG. 1 is a diagram illustrating group-III nitride semiconductor laser device 20 and near-field pattern (NFP) 13 of a laser beam according to an exemplary embodiment of the present disclosure.

Group-III nitride semiconductor laser device 20 according to a first exemplary embodiment includes GaN substrate 1 and active layer 5 provided on GaN substrate 1. The GaN substrate has an oxygen concentration of 5×10¹⁹ cm⁻³ or more. Further, an absorption coefficient of GaN substrate 1 with respect to an oscillation wavelength of active layer 5 is greater than an absorption coefficient of active layer 5 with respect to the oscillation wavelength.

Thereby, stray light 14 is attenuated by GaN substrate 1 and is not guided by GaN substrate 1, and thus it is possible to obtain a unimodal far-field pattern FFP having excellent beam quality.

In this case, it is preferable that the light absorption increases as the oxygen concentration becomes higher, and the oxygen concentration of the GaN substrate is preferably 5×10²¹ cm⁻³ or less. When the oxygen concentration of the GaN substrate exceeds 5×10²¹ cm⁻³, physical properties (structural, optical, and electrical characteristics) of a GaN crystal are changed due to too many impurities, and a function of the laser as a substrate is deteriorated.

Further, an n-type carrier concentration (electron concentration) also increases as the oxygen concentration increases, and an operating voltage decreases as an electrical resistance of the laser on the substrate side decreases. Reliability of device is improved due to the decrease in operating voltage.

As illustrated in FIG. 1, group-III nitride semiconductor laser device 20 may be configured by sequentially laminating, on GaN substrate 1, n-GaN buffer layer 2, n-AlGaN clad layer 3, n-InGaN optical guide layer 4, InGaN-based multiple quantum wells (MQWs) active layer 5, p-InGaN optical guide layer 6, p-AlGaN dad layer 7, and p-GaN contact layer 8, for example. Method of Manufacturing Group-III Nitride Semiconductor Laser Device

Next, a method of manufacturing a group-III nitride semiconductor laser device will be described. The method of manufacturing a group-III nitride semiconductor laser device includes a method of manufacturing a GaN substrate and a method of manufacturing a group-III nitride semiconductor laser device using the GaN substrate.

First, a method of manufacturing a GaN substrate having light absorption characteristics at an oscillation wavelength will be described below. Next, a blue semiconductor laser diode device, which is a group-III nitride semiconductor laser device using the GaN substrate, and a method of manufacturing the same will be described.

### Method of Manufacturing GaN Substrate Having Light Absorption Characteristics of Laser Oscillation Light

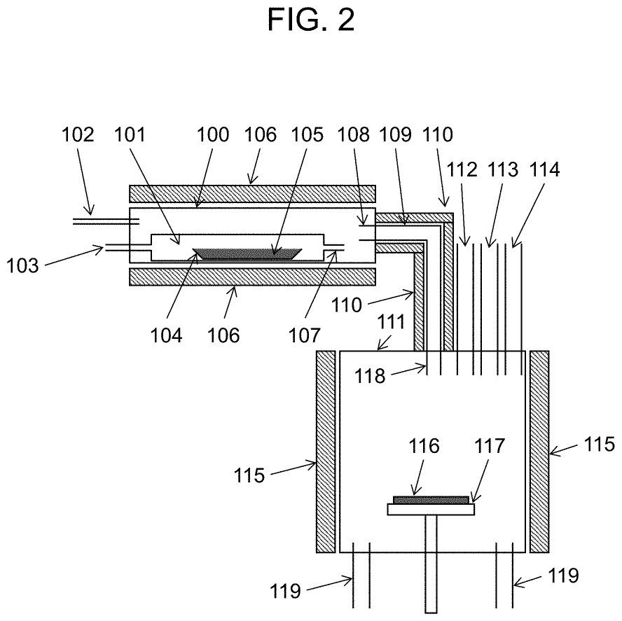

Details of the method of manufacturing a group-III nitride substrate according to the first exemplary embodiment of the present disclosure will be described with reference to a schematic cross-sectional view of an apparatus in FIG. 2. Here, a method of manufacturing a group-III nitride substrate by an OVPE method using liquid Ga as starting group-III element source 105 will be described.

The method of manufacturing a group-III nitride substrate includes a group-III element oxide gas generation step, a group-III element oxide gas supply step, a nitrogen element-containing gas supply step, and a group-III nitride crystal generation step. In the group-III element oxide gas generation step, a reactive gas is reacted with starting group-III element source 105 to generate a group-III oxide gas. In the group-III element oxide gas supply step, the group-III element oxide gas generated in the group-III element oxide gas generation step is supplied to growth chamber 111 in which the group-III nitride crystal generation step is performed. In the nitrogen element-containing gas supply step, a nitrogen element-containing gas is supplied from nitrogen element-containing gas supply port 112 to the growth chamber 111 in which the group-III nitride crystal generation step is performed. In the group-III nitride crystal generation step, a raw material gas supplied into the growth chamber 111 through the respective supply steps is synthesized to manufacture a group-III nitride crystal.

### Group-III Element Oxide Gas Generation Step

In the group-III element oxide gas generation step, first, a reactive gas is supplied from reactive gas supply pipe 103. The supplied reactive gas reacts with Ga as starting group-III element source 105 to generate Ga₂O gas as a group-III oxide gas. The generated Ga₂O gas is discharged from raw material reaction chamber 101 to raw material chamber 100 via group-III oxide gas discharge port 107. The discharged Ga₂O gas is mixed with a first carrier gas supplied from first carrier gas supply port 102 to the raw material chamber, and supplied to group-III oxide gas and carrier gas discharge port 108. In this case, a temperature of first heater 106 is set to 800° C. or higher and lower than 1,800° C. so as to be lower than that of second heater 115, from the viewpoint of a boiling point of Ga₂O gas.

### Starting Ga Source

A starting Ga source is placed in raw material container 104. It is preferable that raw material container 104 has a shape capable of increasing a contact area between the reactive gas and the starting Ga source.

The method of generating the group-III oxide gas is roughly classified into a method of oxidizing starting Ga source 105 and a method of reducing starting Ga source 105.

For example, in the oxidizing method, a non-oxide (for example, liquid Ga) is used as starting Ga source 105, and an oxidizing gas (for example, H₂O gas, O₂ gas, CO gas, or CO₂ gas) is used as the reactive gas. Note that H₂ gas, which is a reducing gas, may be used as the reactive gas only when starting Ga source 105 is liquid Ga. In addition to starting Ga source 105, an In source and an Al source can be adopted as the starting group-III element. On the other hand, in the reducing method, an oxide (for example, Ga₂O₃) is used as starting Ga source 105, and a reducing gas (for example, H₂ gas, CO gas, CO₂ gas, CH₄ gas, C₂He gas, H₂S gas, or SO₂ gas) is used as the reactive gas. In this case, an inert gas or H₂ gas can be used as the first carrier gas.

### Group-III Element Oxide Gas Supply Step

In the group-III element oxide gas supply step, the Ga₂O gas generated in the group-III element oxide gas generation step is supplied to growth chamber 111 via group-III oxide gas and carrier gas discharge port 108, connection pipe 109, group-III oxide gas and carrier gas supply port 118. When a temperature of connection pipe 109 connecting raw material chamber 100 and growth chamber 111 is lower than a temperature of raw material chamber 100, a reverse reaction of a reaction for generating the group-III oxide gas occurs, and starting Ga source 105 precipitates inside connection pipe 109. Therefore, connection pipe 109 is heated by third heater 110 to a higher temperature than first heater 106 so that the temperature of connection pipe 109 is not lower than the temperature of raw material chamber 100.

In addition, mixing of oxygen element into the crystals can be controlled in this step. Specifically, when an oxygen concentration on a back surface side or inner layer side becomes higher and an oxygen concentration on a front surface side becomes lower, a supply amount of the group-III element oxide gas to growth chamber 111 is increased when an inner layer is formed from an early stage to a middle stage, and the supply amount of the group-III element oxide gas to growth chamber 111 is decreased when the front surface side is formed. Furthermore, when the oxygen concentration is gradually changed from the back surface side to the front surface side, the supply amount of the group-III element oxide gas to growth chamber 111 is changed without causing lattice mismatch in the crystals. A specific control method of the group-III oxide gas is performed by controlling a supply amount of the reactive gas of the reactive gas supply step supplied in the group-III oxide gas generation step with a mass flow controller.

The best feature of crystal growth of the group-III nitride substrate according to the exemplary embodiment of the present disclosure by the OVPE method is that it is possible to add oxygen to the GaN crystals to a high concentration by using the group-III element oxide gas as a raw material without deteriorating crystal quality. Although the detailed mechanism is under study, the present inventors assume that it is effective that oxygen is directly bonded to a Ga raw material. The inventors have been able to add oxygen at a concentration up to about 1×10²¹ cm⁻³.

### Nitrogen Element-Containing Gas Supply Step

In the nitrogen element-containing gas supply step, a nitrogen element-containing gas is supplied from nitrogen element-containing gas supply port 112 to growth chamber 111. As the nitrogen element-containing gas, NH₃ gas, NO gas, NO₂ gas, N₂H₂ gas, N₂H₄ gas, HCN gas, and the like can be used. In a carbon element-containing gas supply step, a carbon element-containing gas is supplied from carbon element-containing gas supply port 113 to growth chamber 111. By supplying the carbon element-containing gas, mixing of carbon element into the crystals can be controlled. Examples of the carbon element-containing gas include CH₄ gas, C₂H₆ gas, C₃H₈ gas, C₄H₁₀ gas, C₂H₄ gas, C₃H₆ gas, C₄H₈ gas, C₂H₂ gas, and C₃H₄ gas from the viewpoint of reactivity with the oxide gas other than the Ga source. For a supply concentration of the carbon element-containing gas, the carbon element-containing gas is supplied to growth chamber 111 at a flow rate in a range of 0.01 atm % or more and 30 atm % or less in consideration of concentration control of carbon in the crystals.

### Group-III Nitride Crystal Generation Step

In the group-III nitride crystal generation step, a raw material gas supplied into the growth chamber 111 through the respective supply steps is synthesized to manufacture a group-III nitride crystal. Growth chamber 111 is heated by second heater 115 to a temperature at which the nitrogen element-containing gas reacts with the group-III oxide gas. In this case, growth chamber 111 is heated so that the temperature of growth chamber 111 is not lower than the temperature of raw material chamber 100 to prevent the reverse reaction of the reaction for generating the group-III oxide gas from occurring.

It is necessary to reduce impurities (silicon, chlorine, hydrogen, sodium, magnesium, aluminum, titanium, chromium, iron, nickel, molybdenum, tantalum, and the like) during growth of the group-III nitride crystal, and prevent decomposition of the group-III nitride crystal. Additionally, temperatures of second heater 115 and third heater 110 are the same for a reason for prevention of temperature fluctuation of growth chamber 111 due to the Ga₂O gas generated in raw material chamber 100 and the first carrier gas. Therefore, the temperature of second heater 115 is set to 1,000° C. or higher and 1,800° C. or lower.

By mixing, upstream of seed substrate 116, the group-III oxide gas supplied from growth chamber 111 through the group-III element oxide gas supply step and the nitrogen element-containing gas supplied from growth chamber 111 through the nitrogen element-containing gas supply step, the group-III nitride crystal can be grown on seed substrate 116. In this case, it is preferable that nitrogen element-containing gas supply port 112 and an outer wall of growth chamber 111 are covered with a heat insulating material in order to prevent the decomposition of the nitrogen element-containing gas due to heat from growth chamber 111.

Parasitic growth of the group-III nitride crystal on a furnace wall of growth chamber 111 and substrate susceptor 117 is considered as a problem. Therefore, the concentrations of the group-III oxide gas and the nitrogen element-containing gas are controlled by the carrier gas supplied from second carrier gas supply port 114 to growth chamber 111, such that the parasitic growth of the group-III nitride crystal on the furnace wall of growth chamber 111 and substrate susceptor 117 can be prevented.

Seed Substrate

For example, gallium nitride, gallium arsenide, silicon, sapphire, silicon carbide, zinc oxide, gallium oxide, or ScAlMgO₄ can be used as seed substrate 116. An inert gas or H₂ gas can be used as a second carrier gas.

For a formation of the group-III nitride substrate, a GaN ingot is preferably produced from one crystal growth to cut out the large number of group-III nitride substrates. In addition, a substrate may be produced in one growth without producing the ingot.

An unreacted group-III oxide gas, the nitrogen element-containing gas, the carbon element-containing gas, and the carrier gas are discharged from discharge port 119.

### Evaluation of Crystal Quality of Group-III Nitride Substrate (GaN Substrate)

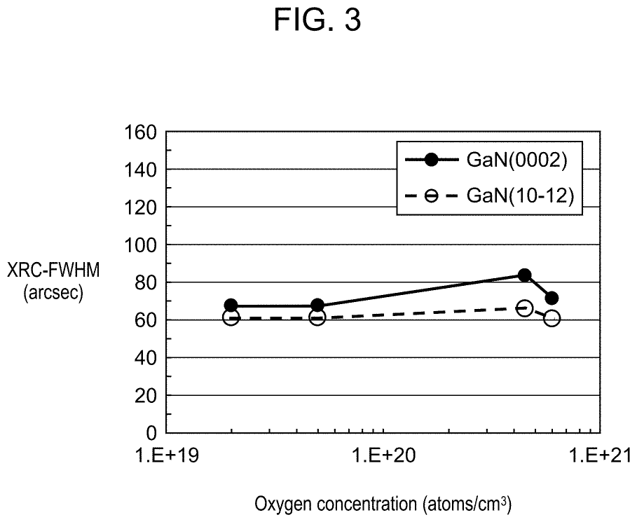

A GaN substrate having a thickness of 400 μm from the GaN crystal ingot produced by the above-described method was sliced to evaluate crystal quality by X-ray diffraction. FIG. 3 is a diagram showing a relationship between a concentration of an oxygen atom in the group-III nitride substrate and a full width at half maximum of an X-ray rocking curve according to the exemplary embodiment of the present disclosure. Here, the oxygen atom concentration was evaluated using secondary ion mass spectrometry (SIMS) measurement. It is shown that both of full width at half maximums of the X-ray rocking curves from a (0002) plane and a (10-12) plane have almost no deterioration after 100 seconds in a range of a concentration of the oxygen atom in the GaN substrate from 2×10¹⁹ cm⁻³ to 6×10²⁰ cm⁻³, and high crystallinity can be thus maintained. A threading dislocation density evaluated by the dark spot density of a cathode luminescence was also about 0.8×10⁵ to 3×10⁵ cm⁻², which shows high crystal quality. The threading dislocation density of about 0.8 to 3×10⁵ cm⁻² shows quality sufficient for ensuring the reliability of the laser diode. Generally, the Miller index is expressed by adding a bar above a number with a negative component, but for convenience of description, the Miller index is indicated by a minus sign in the present disclosure.

### Evaluation of Light Absorption Characteristics of Group-III Nitride Substrate (GaN Substrate)

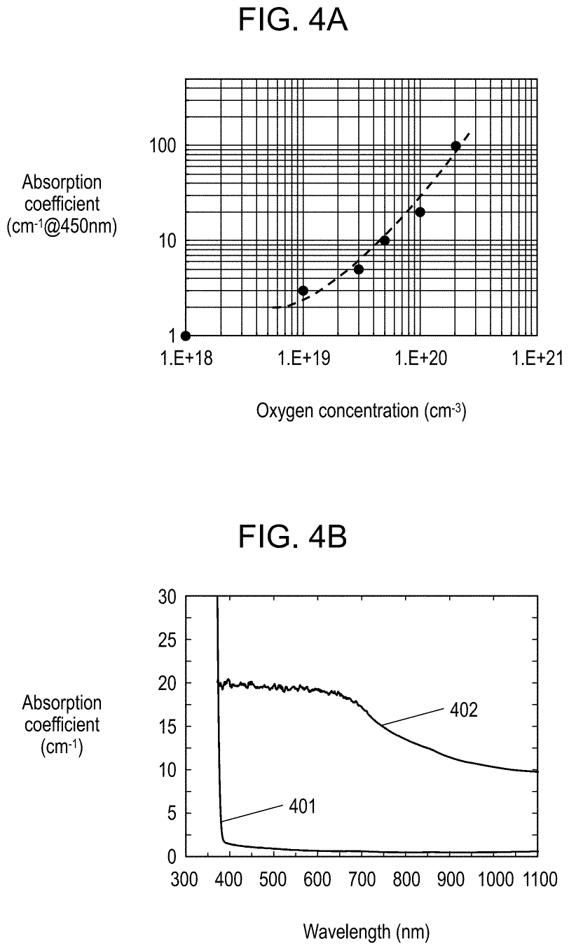

Light adsorption characteristics of the group-III nitride substrate according to the exemplary embodiment of the present disclosure were evaluated. FIG. 4A is a diagram illustrating oxygen atom concentration dependency of the light absorption coefficient at a wavelength of 450 nm of the GaN substrate produced by the OVPE method, and sliced and cut out to a thickness of 400 μm. FIG. 4B is a diagram showing a relationship between the absorption coefficient and the wavelength of the group-III nitride substrate. The absorption coefficient can be determined by, for example, using an ultraviolet visible light spectrophotometer and calculating a kc value from an expression based on Lambert-Beer's law: A=kcd, in which the sample thickness is 1 mm. Here, A represents absorbance, k represents an absorption coefficient, c represents a concentration, and d represents a sample thickness (mm). As a result of consideration in variation between samples and variation between measurements, the light absorption coefficient for visible light when the oxygen atom concentration is 5×10¹⁹ cm⁻³ or more is 10 cm⁻¹ or more, and the light absorption coefficient when the oxygen atom concentration is 1×10²⁰ cm⁻³ or more is 20 cm⁻¹ or more.

For example, as illustrated in FIG. 4B, light is absorbed in curve 402 of an absorption coefficient with respect to a wavelength of the group-III nitride substrate having an oxygen atom concentration of 1×10²⁰ cm⁻³ in an entire visible light wavelength range of 380 nm to 800 nm. The group-III nitride substrate according to the exemplary embodiment of the present disclosure absorbs light equivalent to that of the group-III nitride substrate having the oxygen atom concentration of 1×10²⁰ cm⁻³ in the entire visible light wavelength range of 380 nm to 800 nm. The absorption coefficient uniformly increases with an increase in oxygen concentration in the visible light wavelength range, and the group-III nitride substrate is thus blackened and becomes opaque. As illustrated in FIG. 4B, there is substantially no light absorption in the visible light wavelength range in curve 401 of an absorption coefficient with respect to a wavelength of the group-III nitride substrate having an oxygen atom concentration of 1×10¹⁸ cm⁻³ in a comparative example. A critical significance of the light absorption coefficient according to the exemplary embodiment of the present disclosure will be described later in detail.

Laser Diode Device on GaN Substrate that Absorbs Laser Oscillation Light And Method of Manufacturing the Same

Next, a blue semiconductor laser diode device using the group-III nitride substrate according to the exemplary embodiment of the present disclosure and a method of manufacturing the same will be described.

FIG. 1 is a schematic sectional view illustrating a sectional structure of blue semiconductor laser diode device 20 manufactured on the GaN substrate that absorbs laser oscillation light and having an oscillation wavelength of 455 nm.

This blue semiconductor laser diode device 20 is configured by sequentially laminating, on GaN substrate 1, n-GaN buffer layer 2, n-AlGaN clad layer 3, n-InGaN optical guide layer 4, InGaN-based multiple quantum wells (MQWs) active layer 5, p-InGaN optical guide layer 6, p-AlGaN clad layer 7, and p-GaN contact layer 8, for example. In addition, parts of p-InGaN optical guide layer 6, p-AlGaN clad layer 7, and p-GaN contact layer 8 are removed by etching to form a ridge waveguide having a ridge width of 1.6 μm. Current blocking dielectric film 11 is formed on a side surface of the ridge waveguide, and first p-side electrode 9 and second p-side electrode 12 are provided only on an upper part of the ridge waveguide. In addition, n-side electrode 10 is provided on a back surface of substrate 1.

This blue semiconductor laser diode device is obtained, for example, by the following steps.

(a) First, n-GaN buffer layer 2, n-AlGaN clad layer 3, n-InGaN optical guide layer 4, InGaN-based multiple quantum wells (MQWs) active layer 5, p-InGaN optical guide layer 6, p-AlGaN clad layer 7, and p-GaN contact layer 8 are sequentially laminated on GaN substrate 1 which is set off by 0.4 degrees from a (0001) plane to an a-axis direction by using, for example, a metal organic vapor phase epitaxy (MOVPE) method under a normal atmosphere.
(b) Subsequently, parts of p-InGaN optical guide layer 6, p-AlGaN clad layer 7, and p-GaN contact layer 8 are removed by etching, to form a ridge waveguide having a ridge width of 1.6 μm. Further, current blocking dielectric film 11 is formed on the side surface of the ridge waveguide, and first p-side electrode 9 and second p-side electrode 12 are formed only on the ridge waveguide, thereby allowing a current to flow only into a ridge portion. n-side electrode 10 is formed on the back surface of substrate 1, thereby allowing the current flows in a vertical direction of the laser device.

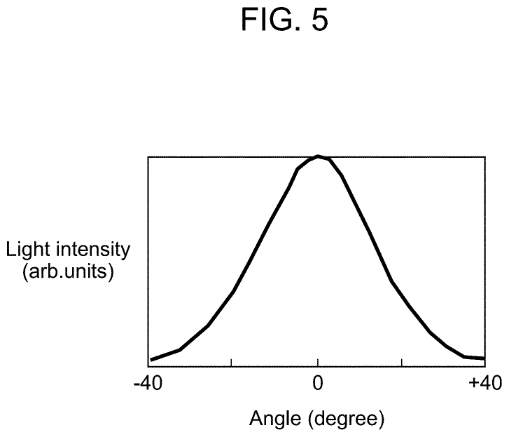

As a result, a blue semiconductor laser diode device is obtained. A length of a resonator of the waveguide is 1 mm, and a surface of the resonator is an m plane formed by cleavage. When the current is injected into the laser diode, laser oscillation occurs in a portion of the ridge waveguide of InGaN-based MQWs active layer 5, which results in near-field pattern (NFP) 13 as illustrated in FIG. 1. Since stray light leaked out of GaN substrate 1 (area indicated by 14 in FIG. 1) is absorbed by GaN substrate 1, the far-field pattern FFP has a unimodal high-quality pattern shape as illustrated in FIG. 5.

In order to reduce an amount of stray light on GaN substrate 1, it is necessary to increase an amount of light confined to InGaN-based MQWs active layer 5. There are several design methods such as increasing a thickness of InGaN-based MQWs active layer 5, increasing an Al composition or a thickness of the p-type and n-type AlGaN clad layers with InGaN-based MQWs active layer 5 sandwiched therebetween, and the like. In any of laminated structures performing the above-described methods, significant distortion is easily caused due to lattice mismatch with respect to the GaN substrate, and crystal defects are easily induced in the laminated structure forming devices, and a wafer itself is easily warped. Therefore, the yield, luminous efficiency, and the reliability may be reduced. Further, when the GaN substrate manufactured by a crystal growth method according to the conventionally HVPE method is added with a large amount of impurities for absorbing laser oscillation light, it is known that the crystal quality is significantly reduced, and the reliability of the laser diode is reduced. As in the present disclosure, since a black GaN substrate manufactured by using the OVPE method can absorb stray light of laser oscillation light while maintaining high crystallinity, a blue semiconductor laser diode device having excellent beam quality can be implemented.

An internal loss of a blue laser having the InGaN-based MQWs active layer depends on a design of the device structure, and is about 10 cm⁻¹ or less. The main factors of the internal loss are light absorption caused by defects and impurities in the crystal forming the active layer and an optical guide layer, and light absorption caused by a formation of a level in a wavelength range longer than an oscillation wavelength range due to a fluctuation of an In composition in InGaN. The GaN substrate according to the exemplary embodiment of the present disclosure has a light absorption coefficient of 10 cm⁻¹ or more when the oxygen atom concentration is 5×10¹⁹ cm⁻³ or more, and can absorb stray light larger than the internal loss. Further, when the light confinement is increased to reduce a laser oscillation threshold current value, guided light is more confined in the InGaN-based MQWs active layer, and an absorption loss due to the fluctuation of the In composition increases, and the internal loss is about 20 cm⁻¹. The GaN substrate according to the exemplary embodiment of the present disclosure has a light absorption coefficient of 20 cm⁻¹ or more when the oxygen atom concentration is 1×10²⁰ cm⁻³ or more, and the crystallinity is not deteriorated. Thus, by adding the oxygen atom at a concentration of 1×10²⁰ cm⁻³ or more to GaN substrate 1, stray light can be absorbed and the beam quality can be improved. The reason that stray light leaked out of the GaN substrate causes a ripple in the far-field pattern FFP is because light oscillated in the active layer is guided in the GaN substrate as a sub-waveguide and mode coupling occurs. When the absorption (internal loss) of the GaN substrate is more than the absorption (internal loss) of the active layer as in the present disclosure, light leaked out of the GaN substrate is further attenuated and the mode coupling does not occur, such that the beam quality can be improved.

In the present disclosure, a blue laser at an oscillation wavelength of 455 nm has been described, but the present disclosure is not limited thereto. Since the group-III nitride substrate according to the exemplary embodiment of the present disclosure absorbs light in the entire visible light wavelength range shorter than the wavelength range of 800 nm, the same effect is obtained in the entire oscillation wavelength range of the active layer, such as ultraviolet, blue-violet, green, yellow, and red wavelength ranges in addition to a blue wavelength range. That is, stray light leaked out from the active layer to GaN substrate 1 (area indicated by 14 in FIG. 1) is absorbed by GaN substrate 1 showing a high absorption coefficient with respect to the oscillation wavelength, and therefore, the far-field pattern FFP has a unimodal high-quality pattern shape as illustrated in FIG. 5.

In the present disclosure, a laser diode of a single transverse mode beam having a ridge stripe width of 1.6 μm is described, but the present disclosure is not limited to this. For example, a 100 W high power laser used for a laser processing machine, a laser display, and the like is a multi transverse mode beam having a ridge width of about 20 to 30 μm. On the other hand, when stray light leaks out of the GaN substrate, variation in beam intensity becomes large and there is a problem in application thereof. Therefore, in the present disclosure, it is effective regardless of whether the beam is the single transverse mode beam or the multi transverse mode beam.

Oxygen impurities described in the present disclosure are impurities in GaN exhibiting n-type conductivity. As the impurities, other elements for generating an n-type carrier such as Si and Se may be contained. Furthermore, the same effect is also obtained in the colored GaN substrate so that p-type impurities such as Mg can be added to absorb light without deteriorating the crystal quality.

Although a Ga plane (+c plane) is used as a crystal plane for crystal growth of the laminated structure of the group-III nitride laser device in this case, it is clear that the same effect is also obtained in manufacture of the laminated structure of the group-III nitride laser device on an N plane (−c plane).

### Comparative Example

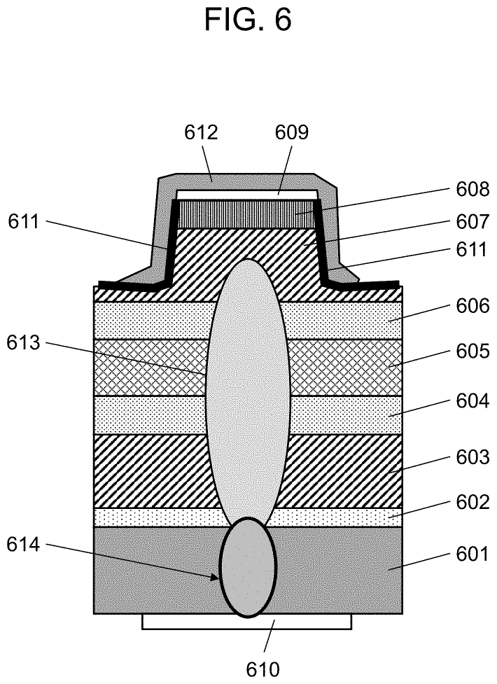

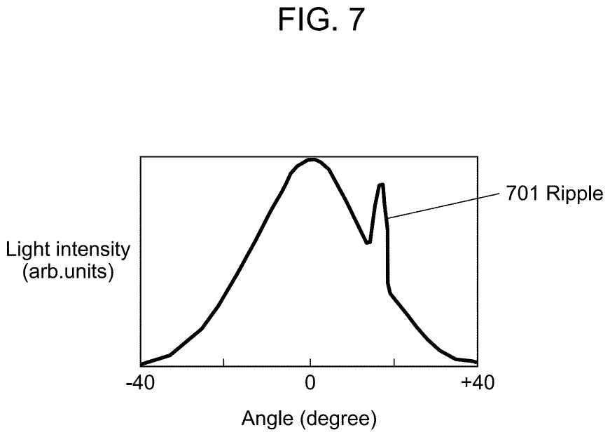

As illustrated in FIG. 6, a structure of the blue semiconductor laser diode as in the above examples of the present disclosure was manufactured, for example, except for using transparent GaN substrate 601 produced by the HVPE growth method and having the oxygen atom concentration of 2×10¹⁸ cm⁻³. The laser beam of the near-field pattern NFP is leaked out of GaN substrate 601, thereby generating stray light 614. As a result, ripple 701 as illustrated in FIG. 7 was generated in the far-field pattern FFP, and the beam quality was deteriorated.

In the present disclosure, arbitrary exemplary embodiments and/or examples of the various exemplary embodiments and/or examples described above can be suitably combined with each other and each effect of the exemplary embodiments and/or examples can be exhibited.

The group-III nitride semiconductor laser device according to the present disclosure makes it possible to provide a group-III nitride semiconductor laser device having the unimodal far-field pattern FFP excellent in beam quality.

According to the present disclosure, the group-III nitride semiconductor laser device can be used for next-generation optical devices such as laser displays and laser diodes (LDs) for industrial laser processing such as metal welding and cutting.

What is claimed is:

1. A group-III nitride semiconductor laser device, comprising:
a GaN substrate; and
an active layer provided on the GaN substrate,
wherein the GaN substrate has an oxygen concentration of 5×10¹⁹ cm⁻³ or more, and
an absorption coefficient of the GaN substrate with respect to an oscillation wavelength of the active layer is greater than an absorption coefficient of the active layer with respect to the oscillation wavelength.

2. The group-III nitride semiconductor laser device of claim 1,
wherein the GaN substrate has an oxygen concentration of 1×10² cm⁻³ or more.

3. The group-III nitride semiconductor laser device of claim 1,
wherein the GaN substrate has a light absorption coefficient of 10 cm⁻¹ or more.

4. The group-III nitride semiconductor laser device of claim 1,
wherein the GaN substrate has an n-type electrical conductivity.
